(19) United States
(12) Patent Application Publication
(10) Pub. No.: US 2007/0092638 A1
(43) Pub. Date: Apr. 26, 2007

(54) Method for the structured metal-coating of polymeric and ceramic support materials, and compound that can be activated and is used in said method

(76) Inventors: Mario Schoedner, Rudolstadt (DE); Hans-Klaus Roth, Laasen (DE); Gulnara Nasmutdinova, Rudolstadt (DE)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(21) Appl. No.: 10/559,112

(22) PCT Filed: Jun. 4, 2004
(86) PCT No.: PCT/DE04/01171

§ 371 Date: Dec. 2, 2005

(30) Foreign Application Priority Data
Jun. 5, 2003 (DE) 10325520.6

(51) Int. Cl. B44C 1/22; H05K 3/00

(52) U.S. Cl. 427/98.6; 216/83

(57) ABSTRACT

The invention is directed to a method for producing highly adhesive conductive structures on nonconductive substrates, in particular for application in electric circuits, and to a surface-activating compound for use in the method. The method comprises the following method steps: application and selective irradiation of a surface-activating compound, and subsequent electroless metallization of the irradiated areas to form metallic structures.

### CROSS-REFERENCE TO RELATED APPLICATIONS

This application claims priority of International Application No. PCT/DE2004/001171, filed Jun. 4, 2004 and German Application No. 103 25 520.6, filed Jun. 5, 2003, the complete disclosures of which are hereby incorporated by reference.

### BACKGROUND OF THE INVENTION

a) Field of the Invention

The invention is directed to a method for the structured metallization of a substrate of polymer material or ceramic material for producing conductive structures for microelectronic applications. It comprises the application of a layer of an optically activatable compound to the substrate material which can be carried out by means of spin coating, a doctor blade process, spraying, printing technique, immersion, or another suitable process, selective irradiation by laser or another suitable light source, and subsequent adherent metallization in the area of the conductive structures to be produced. Depending upon the substrate material that is used, a pretreatment may be advantageous for improving adhesion strength.

The invention is also directed to the composition of an optically activatable compound.

b) Description of the Related Art

It is known that thin palladium acetate films can be acted upon by lasers for the deposition of palladium and can therefore be used as catalysts for subsequent electroless coating with other metals, especially copper. According to the article “VUV synchrotron radiation processing of thin palladium acetate spin-on films for metallic surface patterning”, Applied Surface Science, Vol. 46 (1990) pages 153-157, this palladium deposition process, as it is called, can be carried out using different light sources.

In the article “LAD—a novel, laser-assisted coating process for very-fine conductor metallization”, Galvanotechnik, No. 10, V81 (1990), page 3661, it was found that very fine conductor structures could be generated with the method described above (use of a thin film of palladium acetate solution and subsequent exposure by excimer laser at λ=248 nm followed by selective electroless metallization). However, adequate adhesion strengths cannot be achieved (see also WO 99/05895) except with very high nucleus densities which in turn promote wild growth in the unexposed areas. This must be counteracted by means of time-consuming rinsing processes in which the unexposed layers are removed.

EP 0965656 A1 describes a method for producing a surface activation with a palladium compound which contains a photolabile group as ligands on a substrate comprising an aluminum oxide ceramic wafer with a surface roughness of 0.8 μm. This compound is photochemically active so that it decomposes to metal when exposed to UV radiation of a suitable wavelength. An excimer lamp is indicated as UV source; the compound absorbs in the range of 210 nm-260 nm and 290 nm-330 nm. The drawbacks are long irradiation times (5 to 20 minutes) and heating of the substrate (to 80° C. after 0 minutes).

DE 4124686 A1 discloses a process on a substrate material using laser radiation energy in which copper is precipitated from the gas phase which contains an organic Cu metal complex. This method is disadvantageous in that the structured deposition of copper must be carried out in a vacuum in an inert gas atmosphere. The high costs for apparatus and skilled labor present an obstacle to extensive use of this method in the normal course of manufacture.

U.S. Pat. No. 6,319,564 B1 describes a method for producing conductive structures on a nonconductive substrate material. The heavy metal complex is applied to the entire microporous surface of the substrate material and covers the surface of the substrate material in the area of the conductive structures. According to this invention, the conductive structures are easier to produce than conventional conductive structures. However, the application of this method is limited to microporous surfaces and to the use of a KrF excimer laser (248 nm).

### OBJECT AND SUMMARY OF THE INVENTION

It is the primary object of the invention to develop a method for the selective metallization of polymer substrate materials and ceramic substrate materials which ensures an improved adhesion of the deposited metallic structures, is economical at the same time and can therefore be used more extensively.

Another object of the invention is to find an improved compound for use in a method according to the invention.

This object is met for a method for the structured metallization of polymer substrate materials and ceramic substrate materials comprising the steps of applying a surface-activatable compound containing a nonconductive organic transition metal complex as surface-activating compound, a dicarboxylic acid as cross-linking agent, and melamine resin as complexing agent to the substrate material by suitable coating; selectively irradiating the surface-active compound by light; and subsequently carrying out an electroless metallization of the irradiated areas to form metallic structures in a chemically reductive bath and for a compound for use in this method. The compound is a surface-activating compound for activating the surface of a polymer substrate or ceramic substrate for electroless metallization which comprises a nonconductive organic transition metal complex as activating compound, a dicarboxylic acid as cross-linking agent, and melamine resin as complexing agent.

A method, according to the invention, for the selective metallization of nonconductive polymer substrate materials or ceramic substrate materials comprises the following method steps: coating with an optically activatable transition metal complex compound, excitation of this compound by light (e.g., laser) in order to achieve the activation on the surfaces to be metallized, and subsequent electroless metallization. The coating can be a spin coating, a doctor blade process, spraying, a printing technique, immersion, or another suitable process.

The object of the surface-activating compound is to prepare a surface for activation by radiation and subsequent electroless metallization with a desired conductive material. The activated areas are provided with an adherent metallization by means of the electroless metallization process.

Ceramic materials such as aluminum oxide ceramic, silicon nitride ceramic, aluminum nitride ceramic, barium titanate ceramic, and lead-zirconate-titanate ceramic, and plastics such as polyester (PET, PBT), polyimide, polyamide, PMMA, ABS, polycarbonate, liquid-crystalline polyester (LCP), polyphenylene sulfide, and mixtures of these plastics with other plastics can be used as nonconductive substrate materials.

The method according to the invention makes it possible to produce strongly adhering fine conductive structures of uniform layer thickness with a minimum width of up to 20 μm and good conductivity with short exposure times and is simple and convenient to use

The surface-activating compound comprises a nonconductive transition metal complex based on palladium, platinum, gold, copper or silver as activation compound (the actual effective substance on which the chemical metallization takes place) and a dicarboxylic acid derivative (i.e., a compound from the group of unsaturated carboxylic acid derivatives), e.g., methacrylic anhydride, preferably maleic anhydride, as cross-linking agent and melamine resins as complexing agents.

Palladium diacetate in solution, together with an organic complexing agent, forms a palladium complex. This is indicated by a shift in the absorption band in the UV-visible spectrum as the result of a charge transfer from the ligand to the metal. It is known that stable polyfunctional chelating agents with a plurality of ligator atoms such as N, O, S, P are used as organic complexing agents. In the present invention, the organic complexing agent is a melamine resin of etherified melamine-formaldehyde resin. The function of the cross-linking agent in the process of structuring under the influence of light (laser) is to cross-link the reactive components with one another and/or with the substrate material in order to ensure adhesion to the substrate.

The surface-activating compound is photochemically active in such a way that it decomposes to metal in the presence of light of a suitable wavelength and intensity at room temperature, which initiates the electroless metalization. However, it does not decompose in normal ambient light.

The laser irradiation weakens the metal-ligand bonds which enables the subsequent cleavage or decomposition of the compound to metal in the area of the conductive structures to be generated. Further, it is assumed that by adding maleic anhydride the irradiated surfaces of the surface-activating layer form a network in the form of a polymer coating in which palladium nuclei are embedded. It is possible to implement the cleavage without heating the complex. This prevents melting of the substrate material in the work area.

In a particularly preferred method, the surface-activating compound has a complex compound with palladium as metal. The irradiation is carried out by a Nd:YAG laser at a wavelength of 355 nm and the metal that is subsequently deposited by electroless deposition is copper. The surface-activation can be carried out under atmospheric air pressure.

In another variant of the method, the activation can be carried out by excimer lasers at a wavelength of 248 nm.

Comparable results are also achieved with an argon-ion laser at a wavelength of 488 nm.

The selective irradiation for cleaving the transition metal nucleus from the metal complex only in the areas that are to be metallized can be carried out by applying laser radiation to surfaces and by mask technique as well as by means of a focused laser beam.

With the method according to the invention adherent metallization can be generated on commonly used plastic surfaces such as injection molded articles or sheeting.

When using substrate materials with insufficient adhesion, pretreating in a known manner, e.g., etching with chromic-sulfuric acid, etc., may be advantageous for achieving the desired adhesion strength.

Very fine, sharp structures are made possible by laser irradiation with short wavelengths, e.g., with excimer lasers. In this case, the metallization takes place without wild growth and with very sharp contours of the conductive tracks. It is particularly suitable for the production of two-dimensional or three-dimensional printed circuit board structures.

### DESCRIPTION OF THE PREFERRED EMBODIMENTS

In the following, the invention will be described in more detail with reference to embodiment examples.

In a first embodiment example, a Kapton® 500H polyimide sheet is used as substrate material. For pretreatment, a suitable amount of the Kapton® 500H polyimide sheet is added to 10-percent hydrochloric acid and kept at higher temperatures (possibly boiled) for 10 to 15 minutes. After washing with distilled water and drying in air, the substrates are prepared for the next step. The substrates can be stored for up to 1 month before the next operation.

A polyester sheet with a rough surface (average roughness 0.7 μm) or other substrate materials with a porous surface do not need this pretreatment.

To produce the surface-activating compound, 0.8 to 2.0 parts by weight, preferably 1.0 to 1.3 parts by weight, of palladium diacetate are dissolved in 80 parts by weight tetrahydrofuran, and 0.5 to 1.5 parts by weight, preferably 1.0 to 1.2 parts by weight, of the organic complexing agent melamine resin from etherified melamine-formaldehyde resins are simply dissolved in 20 parts by weight tetrahydrofuran. The two solutions are then mixed and 0.2 to 0.5 parts by weight of maleic anhydride are added. The mixture is ready for further processing.

The resulting surface-activating compound is spun on a substrate at a rotating speed of 1500 min⁻¹ to produce a layer with a thickness of 80 to 100 nm.

The coated substrates are irradiated through a mask by a KrF excimer laser at a wavelength of 248 nm. The surface that is activated in this way can be used directly for electroless copper metallization. However, it can be advantageous to clean the surface by washing off residues of non-irradiated sheeting with solvent, e.g., tetrahydrofuran.

Next, the coated, selectively irradiated substrates are placed in a MacDermid XD-6157-T copper solution for 2 to 10 minutes. The substrates are then rinsed under running deionized water to remove the remaining copper bath residues and then dried at 80° C. in an inert atmosphere for about an hour.

A copper layer having a thickness of 600 nm is formed in the selectively irradiated areas by the method steps specifically described above. The tape test (corresponding to U.S. Standard ASTM B 905 (2000) Standard Test Methods for Assessing the Adhesion of Metallic and Inorganic Coatings by the Mechanized Tape Test) was conducted successfully for the applied copper structure, i.e., a good adhesion of the metallic structure to the substrate was detected.

In a second embodiment example, 0.8 to 2.0 parts by weight, preferably 0.8 to 1.0 pats by weight, of palladium diacetate are dissolved in 50 parts by weight tetrahydrofuran to produce the surface-activating compound. Further, 0.5 to 15 parts by weight, preferably 8 to 10 parts by weight, of the organic complexing agent melamine resin from etherified melamine-formaldehyde resins are dissolved in 50 parts by weight tetrahydrofuran. The two solutions are then mixed and 0.2 to 0.5 parts by weight maleic anhydride are added. The mixture is ready for further processing.

The resulting surface-activating compound is then spun onto the substrate, in this case aluminum oxide, at a rotating speed of 350 min⁻¹ and then dried for 15 minutes at 60° C.

The coated substrates are irradiated by focused frequency-doubled Nd:YAG lasers at a wavelength of 532 nm and, in so doing, are directly structured. The laser output is 5 W and a writing speed of 20 to 50 mm/s is used.

The surface that is activated in this way can be used directly for electroless copper metallization. However, it may also be necessary to rinse the surface in a solvent (tetrahydrofuran) for 1 minute for cleaning by removing residues of non-irradiated areas.

Next, the coated and selectively irradiated substrates are placed in a MacDermid XD-6157-T copper solution for 10 to 20 minutes and electroless metallization is carried out at 70° C. The substrates are then rinsed under running deionized water to remove the remaining copper bath residues and are then dried at 80° C. in an inert atmosphere for 45 minutes.

A copper layer having a thickness of 400 nm was formed in the selectively irradiated areas by carrying out the method according to the second embodiment example.

In a third embodiment example, 0.8 to 2.0 parts by weight, preferably 1.0 to 1.3 parts by weight, of palladium diacetate are dissolved in 50 parts by weight of a solvent mixture of PGMEA (propylene glycol monomethyl ether acetate) and NMP (N-methyl-2-pyrrolidone) in a ratio of 3:1 to produce the surface-activating compound. Further, 5 to 15 parts by weight, preferably 8 to 10 parts by weight, of the organic complexing agent melamine resin from etherified melamine-formaldehyde resins are dissolved in 50 parts by weight of the solvent mixture. The two solutions are then mixed and 0.2 to 0.5 parts by weight of methacrylic anhydride are added. The mixture is ready for further processing.

The resulting surface-activating compound is then spun onto the substrate, in this case polybutylene terephthalate, at a rotating speed of 350 min⁻¹ and is then dried for 15 minutes at 60° C.

The coated substrates are irradiated by an argon-ion laser at a wavelength of 488 nm. The surface that is activated in this way can be used directly for electroless copper metallization. However, it may also be necessary to clean the surface by removing residues of non-irradiated areas by solvents (tetrahydrofuran) for 1 minute.

Next, the coated, selectively irradiated substrates are placed in a MacDermid XD-6157-T copper solution for 10 to 20 minutes and electroless metallization is carried out at 70° C. The substrates are then rinsed under running deionized water to remove the remaining copper bath residues and are then dried at 80° C. in an inert atmosphere for 45 minutes.

The tape test was successfully carried out for the applied copper structure, i.e., a good adhesion of the metallic structure to the substrate was detected.

While the foregoing description and drawings represent the present invention, it will be obvious to those skilled in the art that various changes may be made therein without departing from the true spirit and scope of the present invention.

1-15. (canceled)

16. A method for the structured metallization of polymer substrate materials and ceramic substrate materials, comprising the steps of:
applying a surface-activatable compound containing a nonconductive organic transition metal complex as surface-activating compound, a dicarboxylic acid as cross-linking agent, and melamine resin as complexing agent is applied to the substrate material by suitable coating;
selectively irradiating the surface-active compound by light; and
subsequently carrying out an electroless metallization of the irradiated areas to form metallic structures in a chemically reductive bath.

17. The method according to claim 16, wherein the surface of the substrate of a polymer material is pretreated chemically, physically or thermally in order to roughen it.

18. The method according to claim 17, wherein the substrate is pretreated by etching the substrate surface.

19. The method according to claim 18, wherein the etching solution is a hydrochloric acid solution diluted in water.

20. The method according to claim 18, wherein the etching process tales place by heating the etching solution.

21. The method according to claim 16, wherein the transition metal complex contains palladium.

22. The method according to claim 16, wherein the nonconductive surface-activatable compound is dissolved in a solvent and applied to the substrate in the form of a liquid.

23. The method according to claim 22, wherein the solvent is tetrahydrofuran,

24. The method according to claim 16, wherein the light is laser irradiation at a wavelength of less than 600 nm.

25. The method according to claim 24, wherein the laser radiation is generated with a frequency-doubling or frequency-tripling Nd:YAG laser ((λ=532 nm or 355 nm).

26. The method according to claim 24, wherein the laser radiation is generated by an argon-ion laser ((λ=488 nm).

27. The method according to claim 16, wherein the removal of non-irradiated surface-activating compound after irradiation is carried out in tetrahydrofuran.

28. A surface-activating compound for activating the surface of a polymer substrate or ceramic substrate for electroless metallization comprising a nonconductive organic transition metal complex as activating compound, a dicarboxylic acid as cross-linking agent, and melamine resin as complexing agent.

29. The surface-activating compound according to claim 28, wherein the activating compound is a transition metal complex based on palladium and the dicarboxylic acid, as cross-linking agent, is maleic anhydride.

30. The surface-activating compound according to claim 29, wherein the compound, in relation to a solvent proportion of 100 parts by weight, contains 0.8 to 2.0 parts by weight of palladium diacetate, 5 to 15 parts by weight of melamine resin, and 0.2 to 0.5 parts by weight of maleic anhydride.
